(19) United States
(12) Patent Application Publication
(10) Pub. No.: US 2026/0029774 A1
(43) Pub. Date: Jan. 29, 2026

(54) BACKDRILL TIP OPTIMIZATION

(71) Applicant: DELL PRODUCTS L.P., Round Rock, TX (US)

(72) Inventors: Sandor Farkas, Round Rock, TX (US); Arun Vignesh Palanichamy, Palani (IN); Bhyrav Mutnury, Round Rock, TX (US)

(21) Appl. No.: 18/787,557

(22) Filed: Jul. 29, 2024

(51) Int. Cl. G05B 19/4099; B23B 51/02; H05K 3/00

(52) U.S. Cl. CPC G05B 19/4099; B23B 51/02; H05K 3/0047; B23B 2251/18; G05B 2219/41109; H05K 2203/0207

(57) ABSTRACT

An information handling system stores data associated with one or more drills bits for a backdrill operation of a printed circuit board. The system determines an XY axis tolerance for a via of the printed circuit board. Based on the XY axis tolerance and the signal speed, the system determines an effective Z axis tolerance for the backdrill operation. Based on the determined effective Z axis tolerance, the system determines a tip angle. The system provides the tip angle on a display device.

### FIELD OF THE DISCLOSURE

The present disclosure generally relates to information handling systems, and more particularly relates to backdrill tip optimization for a printed circuit board.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system may store data associated with one or more drills bits for a backdrill operation of a printed circuit board. The system may determine an XY axis tolerance for a via of the printed circuit board. Based on the XY axis tolerance and the signal speed, the system may determine an effective Z axis tolerance for the backdrill operation. Based on the determined effective Z axis tolerance, the system may determine a tip angle. The system may provide the tip angle on a display device.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a diagram of a portion of a printed circuit board according to at least one embodiment of the present disclosure;

FIG. 2 is a block diagram of a portion of an information handling system and a display device according to at least one embodiment of the present disclosure;

FIGS. 3-5 are diagrams of different embodiments of drill bit tip profile according to at least one embodiment of the present disclosure;

FIG. 6 is a flow diagram of a method for determining a drill bit tip profile according to at least one embodiment of the present disclosure; and

FIG. 7 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

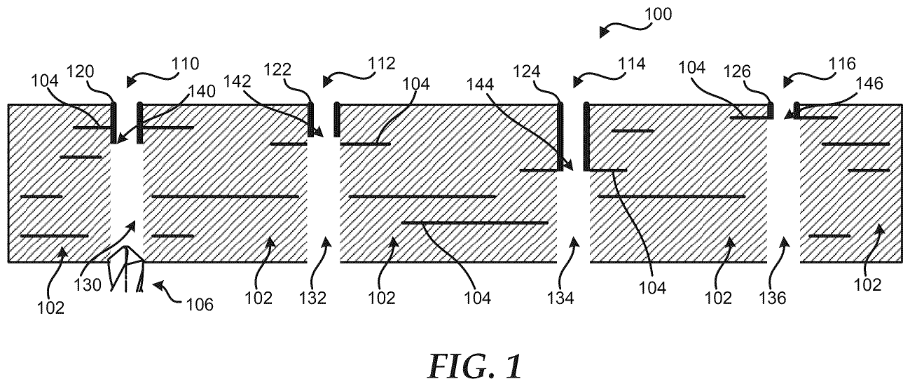

FIG. 1 illustrates a printed circuit board 100 for an information handling system according to at least one embodiment of the present disclosure. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

Printed circuit board 100 includes a substrate 102 and multiple conductive layers 104. In an example, conductive layers may be either ground layers or signal layers. Fabricating a printed circuit board, such as creating vias in the printed circuit board, is known in the art and will not be further disclosed herein, except as needed to illustrate the various embodiments of the present disclosure. Printed circuit board 100 further includes vias 110, 112, 114, and 116. Printed circuit board 100 may include additional components without varying from the scope of this disclosure.

After vias 110, 112, 114, and 116 have been drilled, each of the vias may be plated with a conductive material. For example, via 110 may be plated with conductive material 120, via 112 may be plated with conductive material 122, via 114 may be plated with conductive material 124, and via 116 may be plated with conductive material 126. In an example, the conductive material may be any suitable material including, but not limited to, copper, silver, gold, zinc, and nickel. In certain examples, conductive platings 120, 122, 124, and 126 may be connected to different signal layers 104 within printed circuit board 100.

In an example, signals may be propagated from signal traces on a surface of printed circuit board 100 through a particular conductive material 120, 122, 124, or 126 and into a corresponding signal layer 104. These signals may be any type of signal including, but not limited to, high speed differential signals. In certain examples, a length of a stub of the conductive material that extends beyond signal layer 104 may affect the signal integrity of the signal propagated along the via. Additionally, the longer the stub, the greater affect the stub has on the signal integrity of the propagated signal. The signal integrity of the signal may be further degraded by the stub as the signal speed increases. Thus, the signal integrity may be improved by minimizing the stub lengths of vias 110, 112, 114, and 116.

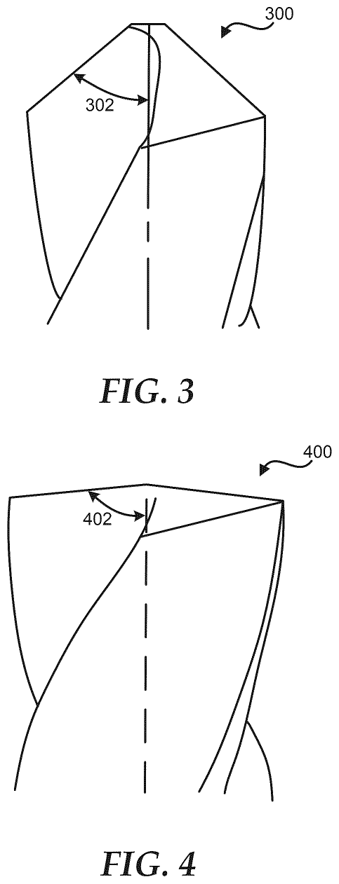

During the fabrication of printed circuit board 100, a drill bit 106 is utilized to backdrill conductive plating 120 of via 110, conductive plating 122 of via 112, conductive plating 124 of via 114, and conductive plating 126 of via 116. In certain examples, drill bit 106 may create a backdrill slot 130 that corresponds to via 110, a backdrill slot 132 that corresponds to via 112, a backdrill slot 134 that corresponds to via 114, and a backdrill slot 136 that corresponds to via 116. Multiple different factors affect the stub length, such as an XY axis tolerance for the via, an angle of the tip of drill bit 106, or the like. In an example, the angle of the tip may be measured from a center axis of drill bit 106 to an edge of the tip as illustrated in FIGS. 3-5 below.

In certain examples, Z axis manufacturing tolerances may cause a drill depth within vias 110, 112, 114, and 116 to be less than the resulting stub length to avoid drill bit 106 from cutting into the must not cut (MNC) layer of the via. As illustrated in FIG. 1, the drill depth of drill bit 106 may result in multiple different backdrill results 140, 142, 144, and 146. In an example, drill bit 106 may not have gone far or deep enough into via 110, such that backdrill result 140 has a stub length that is too long. In this example, the stub length of backdrill result 140 may have a stub length that may result in too much reflection of the signal, such that the stub reduces the signal integrity of the propagated signal. In certain examples, a stub length that is too long may be any length that is greater than 6 mils. One of ordinary skill in the art would recognize that mil is a unit of measurement utilized in routing on printed circuit boards, and one mil equals one-thousandth of an inch or two hundred fifty-four ten-thousandths of a millimeter.

In an example, drill bit 106 may have gone too far or deep into via 112, such that the drill bit cut into the MNC area of via 112 at backdrill result 142. In this example, conductive plating 122 is no longer connected to signal layer 104 at backdrill result 142, such that the propagated signal along via 112 will not enter the signal layer. Drill bit 106 may have gone the proper distance during the backdrill of vias 114 and 116, such that respective backdrill results 144 and 146 have proper connection between the conductive plating and the corresponding layer of printed circuit board 100. For example, backdrill result 144 shows conductive plating 124 in physical and electrical communication with layer 104 without a long stub. Similarly, backdrill result 146 shows conductive plating 126 in physical and electrical communication with layer 104 without a long stub.

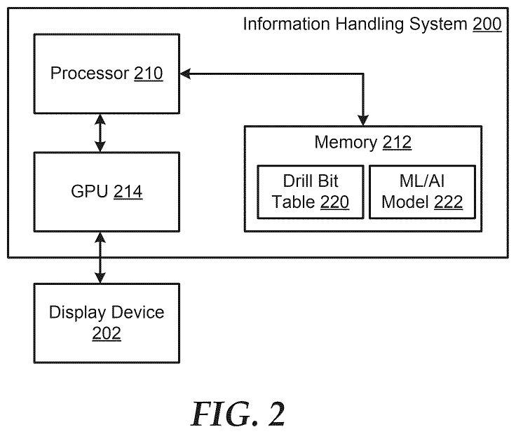

In certain examples, in current printed circuit board manufacturing, the Z height for the backdrill of a via may be 6 mils+/−4, which results in a stub length in the range of 2 to 10 mils. Additionally, if the Z height is 6 mils+/−3, the backdrill operation may result in a stub length in the range of 3 to 9 mils. However, for next generation speeds of signals on vias in printed circuit boards, the few mils of via stub length the better. For example, a processor may utilize a machine learning (ML)/artificial intelligence (AI) model to optimize the tip of a drill bit to minimize a maximum stub length that is left after worst case tolerances during the backdrill process. In an example, the maximum stub length should be less than or equal to 6 mils. As will be described with respect to FIG. 2 below, an optimized tip profile for via 110, 112, 114, and 116 of printed circuit board 100 may be determined based on a Z height, XY axis tolerances of the via, or the like.

FIG. 2 illustrates a portion of an information handling system 200 and a display device 202 according to at least one embodiment of the present disclosure. Information handling system 200 includes a processor 210, a memory 212, and a graphics processing unit (GPU) 214. Memory 212 may store any data associated with processor 210 and GPU 214 including, but not limited to, a drill bit table 220, and ML/AI model 222. In an example, ML/AI model 222 may GPU 214 may communicate with display device 202 to provide any suitable graphical output to a user of the information handling system as will be described herein. Information handling system 200 may include any suitable additional components without varying from the scope of this disclosure.

During operation, processor 210 may execute ML/AI model 222 to determine a drill bit tip optimization for a printed circuit board backdrill operation, such as backdrill operations of vias 110, 112, 114, and 116 in printed circuit board 100 of FIG. 1. In certain examples, ML/AI model 222 may include an input layer, one or more hidden layers, and an output layer. In an example, processor 210 may receive data associated with the vias of the printed circuit board, such as vias 110, 112, 114, and 116 in printed circuit board 100 of FIG. 1, to be backdrilled. For example, processor 210 may receive a Z axis tolerance for the vias, XY axis tolerances, available drill bit tip angles, and signal speeds for each of the vias in the printed circuit board. In an example, processor 210, by execution of ML/AI model 222, may retrieve the available drill bit tip angles from drill bit table 220.

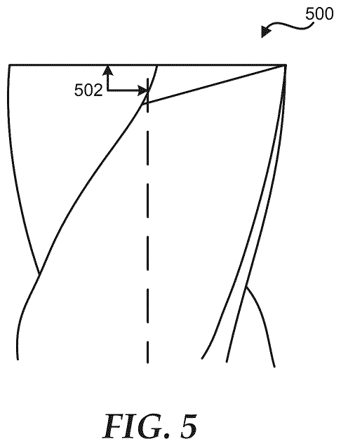

Drill bit table 220 includes the options or available tip angles to be utilized in the backdrill operations. The data within drill bit table 220 will be described with respect to FIGS. 3-5. For example, drill bit table 220 may data associated with drill bit 300 of FIG. 3, drill bit 400 of FIG. 4, and drill bit 500 of FIG. 5. This data may include tip angle 302 for drill bit 300, tip angle 402 for drill bit 400, and tip angle 502 for drill bit 500. In an example, tip angle 302 may be sixty degrees, tip angle 402 may be eighty-five degrees, and tip angle 502 may be ninety degrees.

After receiving the data for the backdrill operation, processor 210 may provide the received data to an input layer of ML/AI model 222. Processor 210 may execute one or more hidden layers of the ML/AI model 222, which in turn may perform any suitable number of operations to determine a drill bit optimization. During execution of ML/AI model 222, processor 210 may perform operations associated with the hidden layers of the ML/AI model to determine the drill bit optimization based on Z axis tolerance for the vias, XY axis tolerances, available drill bit tip angles, and signal speeds for each of the vias in the printed circuit board.

In an example, ML/AI model 222 may be trained to determine an effective Z height tolerance needed for a given speed of a signal to be propagated in the printed circuit board. For example, ML/AI model 222 may be trained to decrease the needed effective Z height tolerance as the speed of the signal increases. Based on the signal speed to be used in the printed circuit board, ML/AI model 222 may determine a maximum Z height tolerance. For example, if a low signal speed will be used in the printed circuit board, processor 210, by execution of ML/AI model 222, may determine that the effective Z height tolerance may be around four mils. If a high signal speed will be used in the printed circuit board, processor 210, by execution of ML/AI model 222, may determine that the effective Z height tolerance may be around three mils.

After the effective Z height tolerance is determined, processor 210, through execution of ML/AI model 222, may determine an optimal tip angle for a drill bit. Any suitable operation may be used to determine the optimal tip angle, such as equation 1 below.

$$Effective Z height tolerance = XY tolerance * cot ( tip angle ) + Z tolerance \qquad EQ . 1$$

As expressed in equation 1, the XY tolerance may be minimized by increasing the tip angle. In an example, a very small taper of a drill bit may be preferred to follow the via barrel and minimize drill wandering. Based on equation 1, if a determined effective Z height tolerance is 4.15 mils, processor 210, through execution of ML/AI model 222, may determine that the optimized tip angle is sixty degrees, such as tip angle 302 of drill bit 300 in FIG. 3. If a determined effective Z height tolerance is 3.35 mils, processor 210, through execution of ML/AI model 222, may determine that the optimized tip angle is eighty degrees, such as tip angle 402 of drill bit 400 in FIG. 4. If a determined effective Z height tolerance is 3 mils, processor 210, through execution of ML/AI model 222, may determine that the optimized tip angle is ninety degrees, such as tip angle 502 of drill bit 500 in FIG. 5.

After the hidden layers are executed, processor 210 may provide the optimized tip angle to the output layer of ML/AI model 222. In an example, processor 210 may provide the optimized tip angle to GPU 214, which in turn may provide the optimized tip angle on a graphical user interface (GUI) on display device 202. A drill bit with the optimized tip angle may be used to backdrill the vias of a printed circuit board, such as vias 110, 112, 114, and 116 of printed circuit board 100 in FIG. 1.

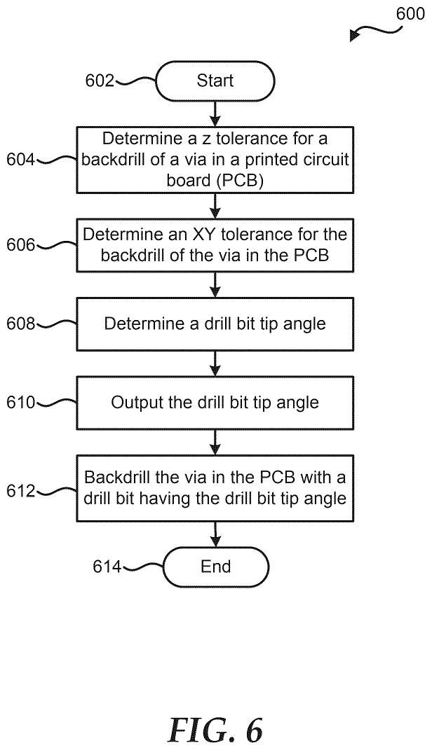

FIG. 6 shows a method 600 for determining a drill bit tip profile according to at least one embodiment of the present disclosure, starting at block 602. Not every method step set forth in this flow diagram is always necessary, and certain steps of the methods may be combined, performed simultaneously, in a different order, or perhaps omitted, without varying from the scope of the disclosure. FIG. 6 may be employed in whole, or in part, processor 210 of information handling system 200 in FIG. 2, or any other type of controller, device, module, processor, or any combination thereof, operable to employ all, or portions of, the method of FIG. 6.

At block 604, a Z tolerance for a backdrill operation of a via in a printed circuit board is determined. In an example, the Z tolerance may be any amount of mils that a drill bit may vary from a desired Z height for the backdrill operation. At block 606, a XY tolerance for the backdrill operation of the via in the printed circuit board is determined. In an example, XY tolerance may be any amount of mils that the drill bit may vary in the XY axis during a backdrill operation.

At block 608, a drill bit tip angle is determined. In an example, the drill bit tip angle is determined based on the Z tolerance, the XY tolerance, and a signal speed for signals to be propagated in the printed circuit board. At block 610, the drill bit tip angle is output. In an example, the tip angle may be provided on a GUI of a display device. At block 612, the via in the PCB is backdrilled with a drill having the drill bit tip angle and the flow ends at block 614.

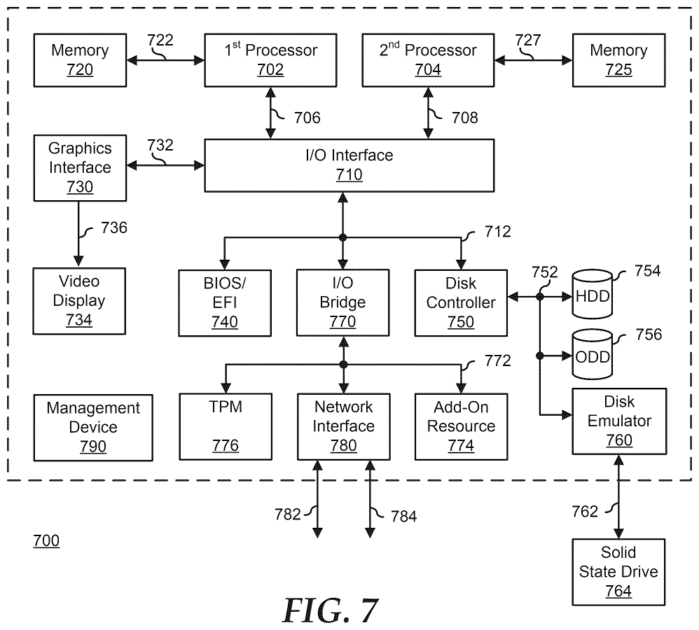

FIG. 7 shows a generalized embodiment of an information handling system 700 according to an embodiment of the present disclosure. Information handling system 700 may be substantially similar to information handling system 200 of FIG. 2. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 700 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 700 can include processing resources for executing machine-executable code, such as a central processing unit (CPU), a programmable logic array (PLA), an embedded device such as a System-on-a-Chip (SoC), or other control logic hardware. Information handling system 700 can also include one or more computer-readable medium for storing machine-executable code, such as software or data. Additional components of information handling system 700 can include one or more storage devices that can store machine-executable code, one or more communications ports for communicating with external devices, and various input and output (I/O) devices, such as a keyboard, a mouse, and a video display. Information handling system 700 can also include one or more buses operable to transmit information between the various hardware components.

Information handling system 700 can include devices or modules that embody one or more of the devices or modules described below and operates to perform one or more of the methods described below. Information handling system 700 includes a processors 702 and 704, an input/output (I/O) interface 710, memories 720 and 725, a graphics interface 730, a basic input and output system/universal extensible firmware interface (BIOS/UEFI) module 740, a disk controller 750, a hard disk drive (HDD) 754, an optical disk drive (ODD) 756, a disk emulator 760 connected to an external solid state drive (SSD) 764, an I/O bridge 770, one or more add-on resources 774, a trusted platform module (TPM) 776, a network interface 780, a management device 790, and a power supply 795. Processors 702 and 704, I/O interface 710, memory 720, graphics interface 730, BIOS/UEFI module 740, disk controller 750, HDD 754, ODD 756, disk emulator 760, SSD 764, I/O bridge 770, add-on resources 774, TPM 776, and network interface 780 operate together to provide a host environment of information handling system 700 that operates to provide the data processing functionality of the information handling system. The host environment operates to execute machine-executable code, including platform BIOS/UEFI code, device firmware, operating system code, applications, programs, and the like, to perform the data processing tasks associated with information handling system 700.

In the host environment, processor 702 is connected to I/O interface 710 via processor interface 706, and processor 704 is connected to the I/O interface via processor interface 708. Memory 720 is connected to processor 702 via a memory interface 722. Memory 725 is connected to processor 704 via a memory interface 727. Graphics interface 730 is connected to I/O interface 710 via a graphics interface 732 and provides a video display output 736 to a video display 734. In a particular embodiment, information handling system 700 includes separate memories that are dedicated to each of processors 702 and 704 via separate memory interfaces. An example of memories 720 and 730 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 740, disk controller 750, and I/O bridge 770 are connected to I/O interface 710 via an I/O channel 712. An example of I/O channel 712 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 710 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 740 includes BIOS/UEFI code operable to detect resources within information handling system 700, to provide drivers for the resources, initialize the resources, and access the resources. BIOS/UEFI module 740 includes code that operates to detect resources within information handling system 700, to provide drivers for the resources, to initialize the resources, and to access the resources.

Disk controller 750 includes a disk interface 752 that connects the disk controller to HDD 754, to ODD 756, and to disk emulator 760. An example of disk interface 752 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 760 permits SSD 764 to be connected to information handling system 700 via an external interface 762. An example of external interface 762 includes a USB interface, an IEEE 4394 (Firewire) interface, a proprietary interface, or a combination thereof. Alternatively, solid-state drive 764 can be disposed within information handling system 700.

I/O bridge 770 includes a peripheral interface 772 that connects the I/O bridge to add-on resource 774, to TPM 776, and to network interface 780. Peripheral interface 772 can be the same type of interface as I/O channel 712 or can be a different type of interface. As such, I/O bridge 770 extends the capacity of I/O channel 712 when peripheral interface 772 and the I/O channel are of the same type, and the I/O bridge translates information from a format suitable to the I/O channel to a format suitable to the peripheral channel 772 when they are of a different type. Add-on resource 774 can include a data storage system, an additional graphics interface, a network interface card (NIC), a sound/video processing card, another add-on resource, or a combination thereof. Add-on resource 774 can be on a main circuit board, on separate circuit board or add-in card disposed within information handling system 700, a device that is external to the information handling system, or a combination thereof.

Network interface 780 represents a NIC disposed within information handling system 700, on a main circuit board of the information handling system, integrated onto another component such as I/O interface 710, in another suitable location, or a combination thereof. Network interface device 780 includes network channels 782 and 784 that provide interfaces to devices that are external to information handling system 700. In a particular embodiment, network channels 782 and 784 are of a different type than peripheral channel 772 and network interface 780 translates information from a format suitable to the peripheral channel to a format suitable to external devices. An example of network channels 782 and 784 includes InfiniBand channels, Fibre Channel channels, Gigabit Ethernet channels, proprietary channel architectures, or a combination thereof. Network channels 782 and 784 can be connected to external network resources (not illustrated). The network resource can include another information handling system, a data storage system, another network, a grid management system, another suitable resource, or a combination thereof.

Management device 790 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 700. In particular, management device 790 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 700, such as system cooling fans and power supplies. Management device 790 can include a network connection to an external management system, and the management device can communicate with the management system to report status information for information handling system 700, to receive BIOS/UEFI or system firmware updates, or to perform other task for managing and controlling the operation of information handling system 700.

Management device 790 can operate off of a separate power plane from the components of the host environment so that the management device receives power to manage information handling system 700 when the information handling system is otherwise shut down. An example of management device 790 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 790 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. An information handling system comprising:
a memory to store data associated with one or more drill bits for a backdrill operation of a printed circuit board; and
a processor to communicate with the memory, the processor to:
determine an XY axis tolerance for a via of the printed circuit board;
based on the XY axis tolerance and a signal speed, determine an effective Z axis tolerance for the backdrill operation;
based on the determined effective Z axis tolerance, determine a tip angle; and
provide the tip angle on a display device.

2. The information handling system of claim 1, wherein the determination of the effective Z axis tolerance includes the processor further to execute a machine learning model.

3. The information handling system of claim 2, wherein the machine learning model includes:
an input layer to receive the XY axis tolerance and the signal speed;
one or more hidden layers to determine the effective Z axis tolerance based on the XY axis tolerance and the signal speed; and
an output layer to provide the determined effective Z axis tolerance.

4. The information handling system of claim 1, wherein the effective Z axis tolerance includes an impact of the XY axis tolerance on a known Z axis tolerance.

5. The information handling system of claim 1, wherein the memory further to store a drill bit table, wherein the drill bit table includes the data associated with the one or more drill bits.

6. The information handling system of claim 1, wherein the data associated with the one or more drill bits identifies a first tip angle for a first drill bit, a second tip angle for a second drill bit, and a third tip angle for a third drill bit.

7. The information handling system of claim 6, wherein the second tip angle is greater than the first tip angle, and the third tip angle is greater than the second tip angle.

8. The information handling system of claim 7, wherein the second tip angle reduces an impact of the XY axis tolerance on a Z axis tolerance as compared to the first tip angle.

9. The information handling system of claim 1, wherein the effective Z axis tolerance indicates a maximum amount a drill bit travels beyond a desired length of the backdrill operation.

10. A method comprising:
storing, by a processor of an information handling system, data associated with one or more drill bits for a backdrill operation of a printed circuit board;
determining an XY axis tolerance for a via of the printed circuit board;
based on the XY axis tolerance and a signal speed, determining an effective Z axis tolerance for the backdrill operation;
based on the determined effective Z axis tolerance, determining a tip angle; and
providing the tip angle on a display device.

11. The method of claim 10, wherein the determining of the effective Z axis tolerance includes executing, by the processor, a machine learning model.

12. The method of claim 11, wherein the determining of the effective Z axis tolerance, the method further includes:
receiving, at an input layer of the machine learning model, the XY axis tolerance and the signal speed;
determining, by one or more hidden layers of the machine learning model, the effective Z axis tolerance based on the XY axis tolerance and the signal speed; and
providing, by an output layer of the machine learning model, the determined effective Z axis tolerance.

13. The method of claim 10, wherein the effective Z axis tolerance includes an impact of the XY axis tolerance on a known Z axis tolerance.

14. The method of claim 10, storing a drill bit table in a memory of the information handling, wherein the drill bit table includes the data associated with the one or more drill bits.

15. The method of claim 10, wherein the data associated with the one or more drills bits identifies a first tip angle for a first drill bit, a second tip angle for a second drill bit, and a third tip angle for a third drill bit.

16. The method of claim 15, wherein the second tip angle is greater than the first tip angle, and the third tip angle is greater than the second tip angle.

17. The method of claim 16, wherein the second tip angle reduces an impact of the XY axis tolerance on a Z axis tolerance as compared to the first tip angle.

18. The method of claim 17, wherein the effective Z axis tolerance indicates a maximum amount a drill bit travels beyond a desired length of the backdrill operation.

19. An information handling system comprising:
a memory to store data associated with one or more drills bits for a backdrill operation of a printed circuit board;
a processor to:
determine an XY axis tolerance for a via of the printed circuit board;
based on the XY axis tolerance and a signal speed, determine an effective Z axis tolerance for the backdrill operation; and
based on the determined effective Z axis tolerance, determine a tip angle; and
a graphics processing unit to provide the tip angle on a display device.

20. The information handling system of claim 19, wherein the effective Z axis tolerance includes an impact of the XY axis tolerance on a known Z axis tolerance.
